(19) United States
(12) Patent Application Publication
(10) Pub. No.: US 2008/0048725 A1
(43) Pub. Date: Feb. 28, 2008

(54) Domino Circuit with Master and Slave (DUAL) Pull Down Paths

(76) Inventor: Zhibin Cheng, Cary, NC (US)

Correspondence Address: IBM CORPORATION, PO BOX 12195, DEPT YXSA, BLDG 002, RESEARCH TRIANGLE PARK, NC, 27709, US

(21) Appl. No.: 11/466,113

(22) Filed: Aug. 22, 2006

(51) Int. Cl. H03K 19/096

(52) U.S. Cl. 326/98

(57) ABSTRACT

A domino circuit and method include a master evaluation node to which a master discharge path with a wide input AND gate is coupled and a virtual evaluation node to which an output stage and slave discharge path are coupled. A current mirror interconnects the master discharge path and the slave discharge path. The devices in the current mirror are sized so that current flowing in the master discharge path is amplified into the slave transmission path.

### CROSS-REFERENCE TO RELATED APPLICATIONS

The present application relates to application Ser. No. ______ (RPS92006028US 1 (4193), assigned to the assignee of the present invention and filed concurrently herewith.

### BACKGROUND OF THE INVENTION

1. Field of the Invention

The present invention relates to integrated circuits, in general and, in particular, to dynamic or domino logic circuits.

2. Background Art

The use of domino logic circuits is well known and documented in the prior art. Such circuits are used to generate particular functions in processors and like electronic devices. In order to generate a particular function, several stages of domino logic circuits are usually coupled or concatenated. In this configuration, one stage provides input to the next stage and so forth.

FIG. 1 shows a schematic for a single stage conventional domino circuit 100 consisting of evaluation node 102 to which output stage 104, leakage tolerant keeper 106, pull down network 103 and PFET 108 are connected. The output stage 104 is an inverter. The leakage tolerant keeper 106 consists of an inverter connected to a PFET. The pulldown network 103 consists of a plurality of NFETs stacked, as shown, to form a wide input AND gate structure.

The circuit in FIG. 1 has two operational phases, namely: charging phase and evaluation phase. During the charging phase, the clock is set to logical “0” (down level). PFET 108 is on and charges node 102 via current I1. The leakage tolerant keeper 106 stabilizes node 102 by supplying current I2 which charges node 102. During the evaluation phase, the clock is at logical “1”, PFET 108 is off and the effect of the inputs IN₁, IN₂, . . . , IN_{N} on evaluation node 102 is determined.

Although the prior art domino circuit of FIG. 1 works well for its intended use, it is relatively slow and susceptible to noise. Stated another way, the prior art domino circuits have problem with speed and noise. The prior art has recognized the problems and has provided variations of the keeper network to solve these problems. Examples of the prior art structures and techniques are set forth in the following U.S. patents and a published paper:

U.S. Pat. No. 6,346,831 B1
U.S. Pat. No. 6,373,290 B1
U.S. Pat. No. 6,549,040 B1
U.S. Pat. No. 6,600,340 B2
U.S. Pat. No. 6,815,977 B2

Moradi, F.; Peiravi, A.; Mahmoodi, H. “A New Leakage-Tolerant Design for High Fan-in Domino Circuits”, Microelectronics, 2004. ICM 2004 Proceedings. The 16th International Conference on 6-8 Dec. 2004 Page(s):493-496.

FIG. 3 shows the circuit described in this article. Even though the circuit is an improvement over prior art circuit discussed above and shown in FIG. 1, it too has some undesirable characteristics. In particular, the configuration of FIG. 3 shows a schematic of a domino style circuit according to the teachings of Moradi et. al. The domino type circuit 300 includes a single evaluation node 301 to which switching device M3, output stage 306, main transmission path 304 and current mirror device 310 are connected. In addition, there are two feedback paths: one feeds the output to a PFET device M5 which serves as a keeper, another feeds the output to a NFET device M9 which fully discharges the evaluation node when the output is high.

The configuration of the domino style shown in FIG. 3 utilizes a single evaluation node 301, which connected two discharge paths together. This configuration creates a noise condition, which permits the unwanted current flow between two paths during evaluation phase. The consequence of this noise condition would degrade the rate of discharge on the evaluation node. Generally, two discharge paths should never be dotted together when they are coupled with a current mirror device; because this circuit topology will cause unexpected performance degradation.

It has been determined neither the traditional keeper approach nor its variations work well with wide input networks such as wide input AND gates. As used in this document wide input network has more than four stacked FETs in the pull down network. For wide input structures a new circuit topology and approach, other than the prior art keeper methodology, is required.

### SUMMARY OF THE INVENTION

The invention relates to a novel dynamic or domino type circuit having a Master transmission path and a Slave transmission path connected to a master and virtual evaluation nodes, respectively. The Master transmission path includes n NMOS transistors or n NFET arranged in a stack. Each of the n NFET has an input to receive in input signal (IN₁, IN₂ . . . INₙ). The Slave transmission path includes at least one NFET with an input to receive a clock signal. A current mirror, preferably formed by two NFETS, couples the Master transmission path to the Slave transmission path. A PFET with an input to receive a clock signal is operatively connected to the virtual evaluation node. An inverter with an output on which an output signal is provided is operatively connected to the virtual evaluation node. The master evaluate on node is driven by a clocked PFET. By separating the evaluation node and connecting the output stage to the virtual evaluation node a more reliable and stable output signal is provided.

The circuit has a charging phase in which the evaluation nodes are charged via the PFETs and an evaluation phase in which the evaluation nodes are discharged, so that the signals on the inputs to respective NFET in the stack can be evaluated at the discharged virtual evaluation node. The discharge is effectuated via the Master and Slave transmission paths. Because the two paths are coupled by the current mirror, a linear relationship exists between currents flowing in respective paths. The width of the NFET, of the current mirror pair, that is located in the Slave path is made much wider than the width of the NFET, of the current mirror pair, located in the Master path. As a consequence, the current flowing in the Slave path is β times greater than current flowing in the Master path, where β depends on characteristics and dimensions of the two current mirror NFETs.

### BRIEF DESCRIPTION OF THE DRAWINGS

FIG. 1 is a schematic of one phase of prior art domino circuit.

FIG. 2 shows empirical waveforms generated by a simulated 8 input AND gate circuit implemented in 65-NM technology. The waveforms are helpful in understanding the problems associated with domino circuits with keeper.

FIG. 3 shows a schematic for Maradi et. al. prior art circuit listed above.

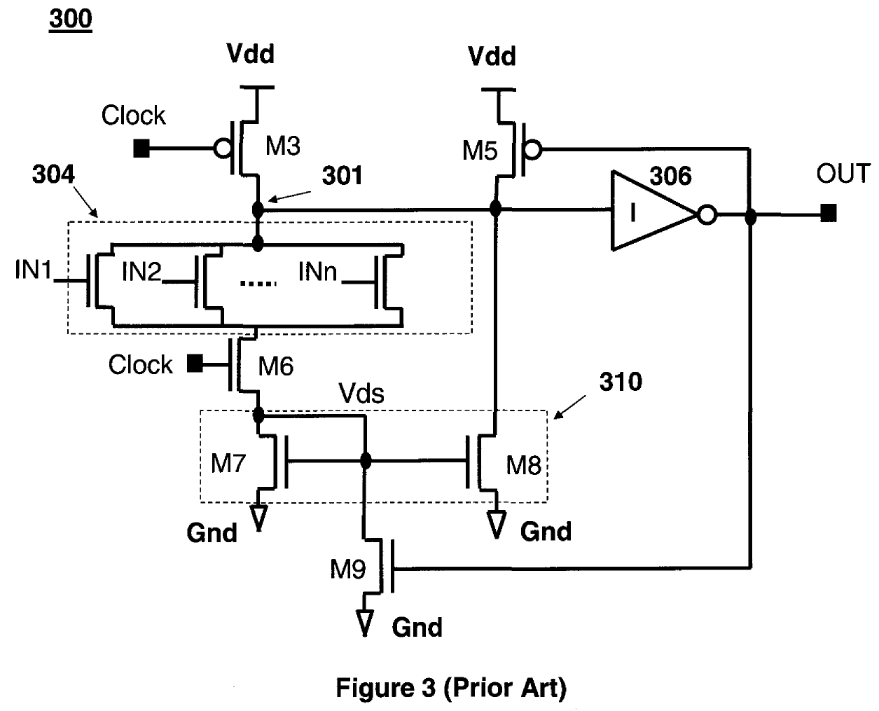

FIG. 4 shows a schematic for one phase of domino circuit according to teachings of the present invention.

FIG. 5 shows empirical waveforms generated from a simulated 8 input AND gate domino circuit implemented in 65-NM technology according to teachings of the present invention.

### DETAILED DESCRIPTION OF AN EMBODIMENT OF THE INVENTION

The present invention presents a domino style circuit in which a current mirror coupling a slave transmission control path and master transmission path discharge a virtual evaluation node and master evaluation node, respectively. This approach solves problem in prior art domino style circuits. Before describing details of the circuit according to teachings of the present invention, a description of the problem which the inventor discovers and solve will be given. As a consequence, the discovery of the problem is part of the present invention.

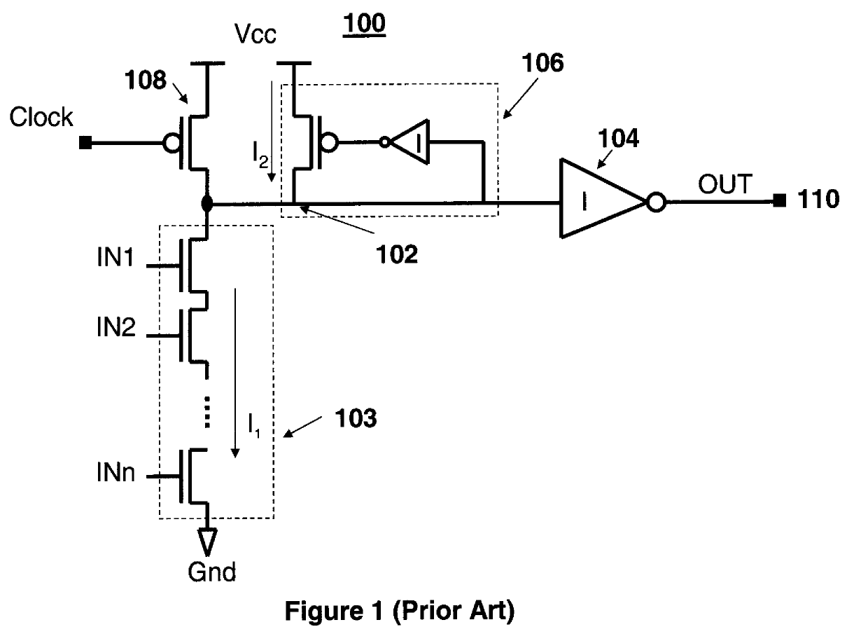

FIG. 1 shows the prior art domino type circuit having pulled down network 103 and keeper circuit 106 connected to a single evaluation node 102. The pulled down network 103 consists of a plurality of NFET stacked or connected in series to evaluation node 102. Current I2 flows in keeper circuit 106 and current I1 flows in pulled down network 103. During the evaluation phase when the clock single is high (logical “1”) I1 and I2 could cause a race condition resulting in error at the output 110 of the circuit. Due to the race condition the evaluation node is never fully discharge; so the output never changes state.

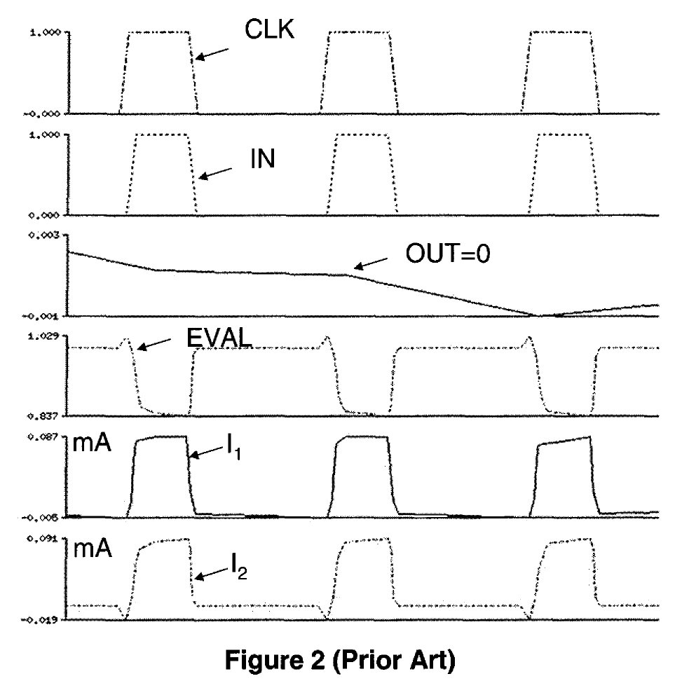

FIG. 2 shows simulated waveforms associated with a domino style circuit such as the one set forth in FIG. 1. The circuit with which the empirical waveform of FIG. 2 is associated was implemented in 65-nm technology. An 8 input AND gate represents the pull down circuit in FIG. 1 and the PFET in the keeper circuit 106 is a relatively small device. Viewing the waveform in FIG. 2 from top to bottom, the first waveform represents the clock signal in its high state. As shown in the figure the clock pulses extend from 0 volt to 1 volt. The second waveform represents the IN signal supply on the input IN₁ through INₙ (FIG. 1). The third waveform represents the output of the circuit at node 110 (FIG. 1). As marked in the figure this output is substantially 0, an error condition. The fourth waveform shows behavior of the signal generated at evaluation node 102. As shown in the sketch the signal swings from 0.037 volts to less than 1 volt. At no time the signal ever reaches 0 which indicates the node is never fully discharge and as a result causes error at the output. The fifth and sixth waveforms represent the current I1 and I2, respectively. As is obvious from the waveforms both I1 and I2 has substantially the same magnitude and as a result contention between these two currents result in error at the output of the circuit.

Based upon the simulated results the following conclusion is reached. The circuit fails to respond to the input signal at the evaluation node because the pull down current I1, in the resistive path, is relatively weak when evaluation starts. The evaluation node attempts to respond to the input signal but its voltage level can only drop to 837 mv that is incapable to turn on the small inverter in front of the PFET in keeper circuit 106 (FIG. 1). As a consequence, the keeper is continuously charging the evaluation node with I2 which is unexpectedly against the pull down current I1. Both I1 and I2 remain at the same magnitude approximately 85 ma. In addition, the voltage at the evaluation node fails to turn on the output inverter 104 (FIG. 1) resulting in an erroneous output. This study indicates the use of keeper circuit on a rather resisted pull down domino path must be used with caution else the output from the circuit could be erroneous. In particular, when the pull down AND gate accommodates more than 4 inputs the likelihood of errors appears to be high. As a consequence, it is determined that the keeper degrades not only the performance on circuit delay and/or noise immunity but also causes a logic error in the case of wide AND gate pull down circuit.

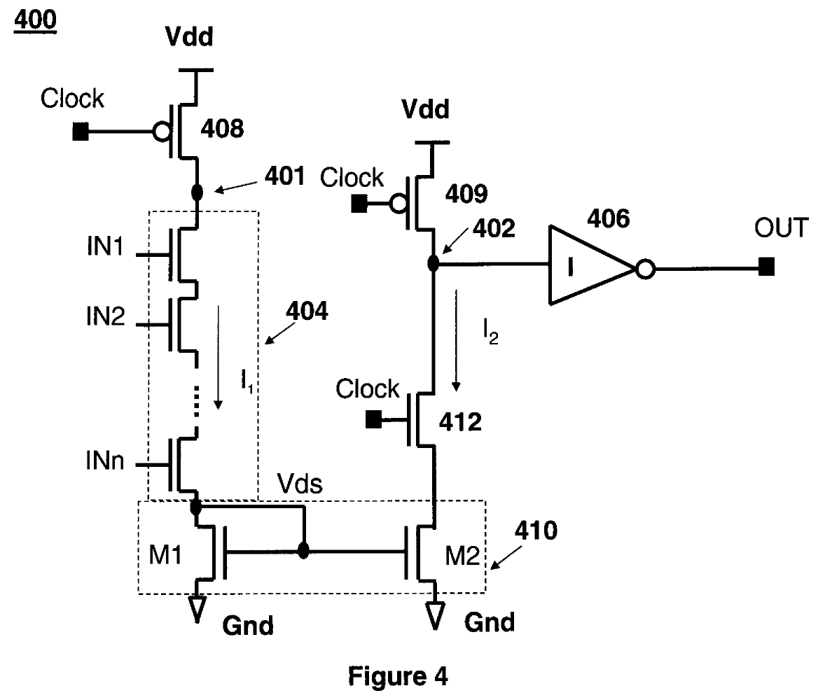

FIG. 4 shows a schematic of a domino style circuit according to the teachings of the present invention. The domino type circuit 400 includes master evaluation node 401 to which switching device 408 and master transmission paths are connected. The domino type circuit, also, includes virtual evaluation node 402 to which switching device 409, slave transmission path including device 412 and output stage 406 are connected. The switching devices include PFET devices. Each of the PFET devices has one terminal connected to a power supply Vdd, another terminal connected to master evaluation node 401 or virtual evaluation 402, and a third terminal connected to a clock (CLK). Depending on the state of the clock the switching device charges the evaluation nodes. In the preferred embodiment of this invention the switching device includes PFET. The output stage 406 includes a device having a terminal connected to virtual evaluation node 402 and output from which the output signal is provided. In the preferred embodiment of this invention the output stage 406 includes an inverter.

Still referring to FIG. 4 the master transmission path connected to 401 includes pull down network 404 to which a current source M1 is connected. In the preferred embodiment of this invention the master transmission path includes a plurality of NFETs connected in series to the master evaluation node 401. Each of the NFET in the pull down network includes the terminal for receiving an input IN1 through IN. The slave transmission control path connected to virtual evaluation node 402 includes a switch device 412 with one terminal connected to virtual evaluation node 402 and an input terminal for receiving clock signals. A third terminal of the switch device 412 is connected to current source M2. In the preferred embodiment of this invention switching device 412 is a NFET and current source M2 includes an NFET. The current sources M1 and M2 form a current mirror that reflects current I1 flowing in the master path into current I2 flowing in the slave control path. To this end the gate electrode of M1 and M2 are interconnected and the drain of M1 is connected to the gate of M1 and M2 respectively.

In summary, the master-slave domino logic style of the present invention includes a wide AND gate domino logic structure with n inputs as shown in FIG. 4. It includes an input dependent path and a secondary path. I call them master and slave. In the master, n nMOS or NFET transistors are in a stack which is connected to an nMOS current source transistor M₁. In the slave an NMOS or NFET transistor is connected to an nMOS current source transistor M₂. The gates of M₁ and M₂ are connected to form a current mirror pair. A linear relationship between I₁ and I₂ is established as long as I1 exists, such that I₂=βI₁, where β depends on the characteristics and dimensions of M₁ and M₂.

I assume M₁ and M₂ have the same threshold voltage in this application, so transistor M₂ is designed much wider than M₁ to achieve high performance. This simple link between gates increases the initial pull-down current by β times and map it into the slave path. No traditional keeper is needed for this domino circuit. The slow pull-down path of the traditional keeper is replaced with fast pull down paths. To reduce the time used for early detection of input logic information, we apply current mirror technique on both paths. This definitely increases the sensitivity of the circuit to the input signals and robustness to the noise. As soon as the information on the existence and magnitude of discharging current inside the master path passes to the slave path, it discharges at a much higher speed, which can be designed independently of input logic, when evaluation takes place. The master-slave domino logic increases the rate of voltage drop at the evaluation node and reduces the evaluation time. The master-slave domino logic keeps two evaluation nodes 401 and 402 separated, such that there is no direct connection between the master and slave paths, which effectively eliminates the crossing currents between them during evaluation and consequently suppresses the noise generated by theses current in the evaluation and output nodes. The technique of the present invention is applicable to any type of domino logic with a resistive pull-down or pull-up network.

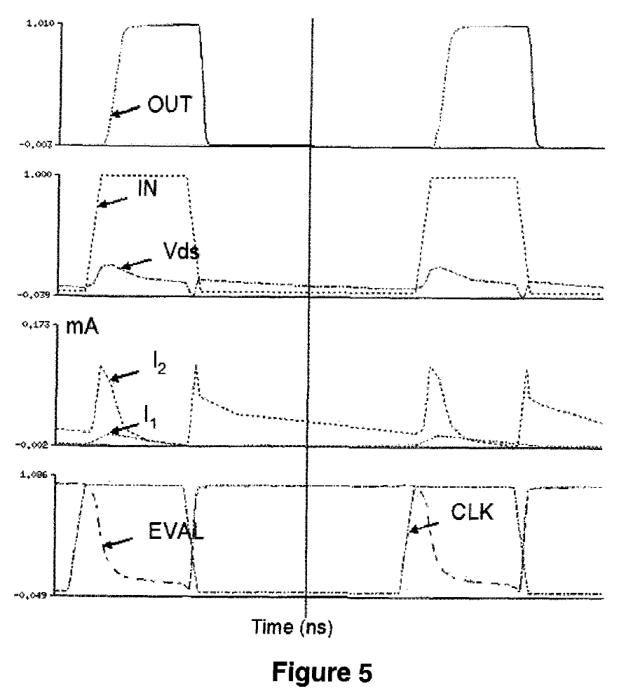

FIG. 5 shows empirical waveforms associated with the circuit of FIG. 4 comprising an eight-way input AND gate in 65-nm technology with the power supply Vdd equal 1.0v. The inputs of the eight-way AND gate was simulated with real signals. Viewing the waveforms in FIG. 5 from top to bottom the first waveform represents the signal that is output from the circuit of FIG. 4. The second waveform represents the signal IN which was applied to each of the input terminals of the eight-way AND gate. Vds, second waveform, represents the voltage between the drain and source of M1 (FIG. 4). The third set of waveforms represent the current I1 and I2 flowing in the master transmission path and slave transmission control path, respectively. The last of the waveform in FIG. 5 shows the voltage at the virtual evaluation node. In FIG. 5 time is represented on the horizontal axis. The vertical line distinguishes between cycles of the system. In particular, waveform to the left of the vertical line is repeated on the right side of the line. Therefore, only waves on the left side of the vertical line need to be discussed since the others are a repeat of this basic set of waveforms.

Still referring to FIG. 4 and FIG. 5, inputs IN, through INN, N=8, were represented by real input signals. During the up phase of the clock, the evaluation node was evaluated. The circuit of FIG. 4 responds to input signal IN (second waveform from top) equals 1 volt. Current I1 flows in the master path whereas current I2 flows in the slave path and Vds is generated across M1. Both currents increase to their maximum value quickly and cause M2 to saturate acting as a current source during the input transition. The current I2 increases at a much higher rate during the same period its magnitude is amplified for achieving a particular performance requirement. The magnitude of the current is determined only by the width of transistor bias with Vds.

In the preferred embodiment of this invention I2 is about ten times as much as I1 in this case. The increase discharging current I2 in the slave transmission control path greatly increase the rate of voltage drop of the evaluation node. Our simulation also indicates the domino style circuit according to the teachings of the present invention exhibits a great deal of robustness in responding to noise. In particular, the simulation indicates the circuit according to the teachings of the present invention has a 40% margin to noise.

The domino style circuit according to the teachings of the present invention is a high speed noise tolerant master-slave domino circuit which can be used to generate various complex logic expressions in timing critical units of microprocessors. It is designed to be extremely sensitive to the input signal with a great degree of robustness to the noise. The circuit according to the teachings of the present invention provides a complimentary solution for wide pull down domino circuit where conflicts between performance and noise can not be eliminate using FET base keeper techniques. Other type of domino circuit such as OR domino type style circuit may also be replaced by the teachings of the present invention. The invention contains no feedback path which reduces the output load and it also reduces the leakage current during the pre-charge phase. The invention improves the sensitivity of domino circuits and reduces time used to distinguish real signal from the noise. The teaching of the present invention is not limited to high pull down circuit. It is also applicable to other type of domino styles where the pull down or pull up path is highly resistive.

Even though the invention has been described with respect to a particular illustrative embodiment, it is to be understood the invention is not limited to details of the above embodiment. Also, modifications can be made by those having ordinary skill in the art without departing from the spirit and scope of the invention set forth in the claims.

What I claim is:

1. A circuit comprising:
a first evaluation node;
a second evaluation node;
at least one source providing current to charge the first evaluation node and the second evaluation node, respectively;
a master logic discharge path operatively coupled to the first evaluation node;
a slave logic discharge path operatively coupled to the second evaluation node; and
a circuit arrangement operatively interconnecting the master logic discharge path and the slave logic discharge path.

2. The circuit of claim 1 further including an output stage for outputting an output signal operatively coupled to the second evaluation node.

3. The circuit of claims 1 wherein the source includes at least one switching device having at least one terminal for receiving a clock signal and another terminal to couple to a power supply.

4. The circuit of claim 3 wherein the switching device includes a PFET.

5. The circuit of claim 1 wherein the master logic discharge path includes a wide input AND gate.

6. The circuit of claim 5 wherein the wide input AND gate includes n devices arranged in stacked configuration.

7. The circuit of claim 6 wherein each of the n devices includes at least one input for receiving an input signal.

8. The circuit of claim 7 wherein the n devices includes nFET.

9. The circuit of claim 1 wherein the slave logic discharge path includes a switching device with at least one terminal to receive clock signals.

10. The circuit of claim 9 wherein the switching device includes an NFET.

11. The circuit of claim 1 wherein the circuit arrangement includes a current mirror.

12. The circuit of claim 11 wherein the current mirror includes a pair of current source devices wherein one of said pair of current source devices is operatively positioned within the Master logic discharge path and the other of said pair of current source devices operatively positioned within the Slave logic discharge path and a first conductive member interconnecting the pair of current source devices.

13. The circuit of claim 12 wherein the pair of current source devices includes a pair of nFETs.

14. The circuit of claim 12 further including a second conductive member interconnecting a drain electrode and gate electrode of the nFET located within the master logic discharge path.

15. The circuit of claim 12 wherein characteristics and dimensions of the pair of nFET are such that when a current flows in Master logic discharge path said current is magnified and flows in said Slave logic discharge path.

16. A current mirror circuit comprising:
a first nFET having a gate electrode and a drain electrode;
a first transmission medium interconnecting the gate electrode to the drain electrode;
a second nFET having a drain electrode and a gate electrode; and
a second transmission medium interconnecting the gate electrode of the first nFET and the gate electrode of the second nFET, wherein a width of the second nFET is greater than a width of the first NFET.

17. A circuit comprising:
a first transmission path including n switching devices arranged in a stack configuration, wherein each of the n switching devices includes an input to receive input signal;
a first current source device operatively coupled to one of the n switching devices;
a conductive medium interconnecting a first electrode to a second electrode of said current source;
a second transmission path positioned in parallel to the first transmission path and including at least one switching device with an input to receive a clock signal; and
a second current source device having a first electrode operatively coupled to the at least one switching device and a second electrode operatively coupled to the second electrode of said first current source device.

18. The circuit of claim 17 wherein the n switching devices include NFETs.

19. The circuit of claim 17 wherein the first current source and second current source are NFETs.

20. The circuit of claim 17 wherein the at least one switching device is an NFET.

21. A method comprising:
providing a first evaluation node and a second evaluation node;
providing switching devices for charging the first evaluation node and the second evaluation node when a clock signal is in a first phase;
providing in a first path a network to conduct discharge current from said first evaluation node when the clock signal is in a second phase;
providing in a second path a second switch device for conducting discharge current from said second evaluation node when the clock is in said second phase; and
mirroring, with a current mirror, the discharge current flowing in said first path to the second path.

22. The method of claim 21 further including increasing the magnitude of discharge current mirrored from the first path into the second path.

23. The method of claim 21 wherein amplification of the discharge current is based upon characteristics and dimensions of devices forming the current mirror.

24. The method of claim 21 further including applying input signals to at least one device located in the network.

25. The method of claim 23 further including monitoring said second evaluation node to detect effect of said input signals.

26. The method of claim 24 wherein the monitoring occurs subsequent to the second evaluation node being fully discharged.
